(19) United States
(12) Patent Application Publication
(10) Pub. No.: US 2026/0078482 A1
(43) Pub. Date: Mar. 19, 2026

(54) MAGNETIC RECORDING MEDIUM PRODUCTION APPARATUS, MAGNETIC RECORDING MEDIUM PRODUCTION METHOD, AND VARNISHING DEVICE

(71) Applicant: Resonac Hard Disk Corporation, Chiba (JP)

(72) Inventors: Noriya SEIKI, Chiba (JP); Yoshihito SUEOKA, Chiba (JP); Shinya SATO, Tokyo (JP); Koji ITOKAZU, Chiba (JP); Michitaka TAKASAKI, Chiba (JP)

(21) Appl. No.: 19/330,020

(22) Filed: Sep. 16, 2025

(30) Foreign Application Priority Data
Sep. 19, 2024 (JP) 2024-162289

(51) Int. Cl. C23C 14/56; C23C 14/24; C23C 14/58; G11B 5/84

(52) U.S. Cl. CPC C23C 14/568; C23C 14/24; C23C 14/588; G11B 5/8416

(57) ABSTRACT

A magnetic recording medium production apparatus includes a film deposition device that forms a magnetic recording layer and a protective layer on a substrate, in the stated order; a lubricant application device configured to form a lubrication layer by applying a lubricant on the protective layer formed by the film deposition device; a varnishing device configured to perform a varnishing process, with a polishing material, on a surface of the lubrication layer applied by the lubricant application device; a processor; and a memory that includes instructions, which when executed, cause the processor to execute collecting data on a load amount during the varnishing process; storing the collected data on the load amount; performing an operation by using the stored data on the load amount; and setting a manufacturing condition of the film deposition device or the lubricant application device based on an operation result obtained by performing the operation.

### CROSS-REFERENCE TO RELATED APPLICATIONS

This application is based on and claims priority to Japanese Patent Application No. 2024-162289, filed on Sep. 19, 2024, the entire contents of which are incorporated herein by reference.

### FIELD

The present invention relates to a magnetic recording medium production apparatus, a magnetic recording medium production method, and a varnishing device.

### BACKGROUND

In recent years, magnetic storage devices have been installed in various products such as personal computers, video recorders, and data servers, and their importance has increased. A magnetic storage device is a device having a magnetic recording medium for storing electronic data by magnetic recording, such as a hard disk drive (HDD).

A general magnetic recording medium is produced through a film deposition process in which an underlayer, an intermediate layer, a magnetic recording layer, and a protective layer are formed in this order on a nonmagnetic substrate by using a film deposition device; a lubricant application process in which a lubrication layer is applied to the surface of the protective layer by using a lubricant application device; a subsequent varnish process in which the surface of the lubrication layer is polished by using a varnishing device in order to remove foreign matter and protrusions from the surface of the lubrication layer; and an inspection process in which an inspection device is used for inspection.

Japanese Unexamined Patent Application Publication No. 2010-79955 (Patent Document 1) discloses a tape varnishing device used for the production of a magnetic recording medium.

### SUMMARY

According to one embodiment of the present disclosure, a magnetic recording medium production apparatus includes a film deposition device configured to form at least a magnetic recording layer and a protective layer on a substrate, formed in an order of the magnetic recording layer followed by the protective layer; a lubricant application device configured to form a lubrication layer by applying a lubricant on the protective layer formed by the film deposition device; a varnishing device configured to perform a varnishing process, with a polishing material, on a surface of the lubrication layer applied by the lubricant application device; a processor; and a memory that includes instructions, which when executed, cause the processor to execute collecting data on a load amount during the varnishing process; storing the collected data on the load amount; performing an operation by using the stored data on the load amount; and setting a manufacturing condition of the film deposition device or the lubricant application device based on an operation result obtained by performing the operation.

### BRIEF DESCRIPTION OF THE DRAWINGS

FIG. 1 is a diagram illustrating the configuration of a magnetic recording medium production apparatus according to an embodiment;

FIG. 2 is a cross-sectional view illustrating an example of a magnetic recording medium produced by the magnetic recording medium production apparatus according to an embodiment;

FIG. 3 is a diagram illustrating the relationship between the load amount during varnish processing and the film thickness of the lubrication layer;

FIG. 4 is a diagram illustrating the relationship between the load amount during varnish processing and the surface roughness of the processing target;

FIG. 5 is a plan view of a film deposition device according to an embodiment;

FIG. 6 is a side view of a chamber of a film deposition device according to an embodiment;

FIGS. 7A and 7B are schematic diagrams of a lubricant application device that performs a dip method;

FIG. 8 is a schematic diagram of a lubricant application device that performs a spin coat method;

FIG. 9 is a schematic diagram of a lubricant application device that performs a vapor method;

FIG. 10 is a schematic diagram of a varnishing device according to an embodiment;

FIG. 11 is an enlarged cross-sectional view illustrating an example of a polishing tape used for varnishing;

FIGS. 12A and 12B are diagrams for explaining a varnishing process.

### DESCRIPTION OF THE EMBODIMENTS

Because a magnetic recording medium is produced through a long process as described above, even if a defective product is detected in the inspection process, there may be many defective products in the production line at that time. In the magnetic recording medium production apparatus having a conventional varnishing device, even if a defective product is generated in a process prior to the varnish process, the varnishing device performs polishing of the surface of all lubrication layers sent after the process prior to the varnish process. Therefore, in order to reduce the number of defective products generated in the magnetic recording medium production apparatus, it is necessary to detect the generation of defective products as early as possible, or to predict the generation of defective products, to thereby manage the production apparatus in an optimum condition.

In view of the above, it is an object of one embodiment of the present disclosure to provide a magnetic recording medium production apparatus, a magnetic recording medium production method, and a varnishing device, which can enhance the productivity of the magnetic recording medium by detecting or predicting, at an early stage, the occurrence of defects in the production of the magnetic recording medium.

Embodiments of the present invention will be described in detail below with reference to the drawings. In order to facilitate understanding of the description, the same reference numerals are assigned to the same components in the drawings, and duplicate descriptions are omitted. The scale of each member in the drawings may be different from the actual scale. In the present specification, the expression “X to Y” indicating a numerical range means that the numerical values described before and after “to” are included as the lower limit and upper limit unless otherwise specified.

### <Magnetic Recording Medium Production Apparatus>

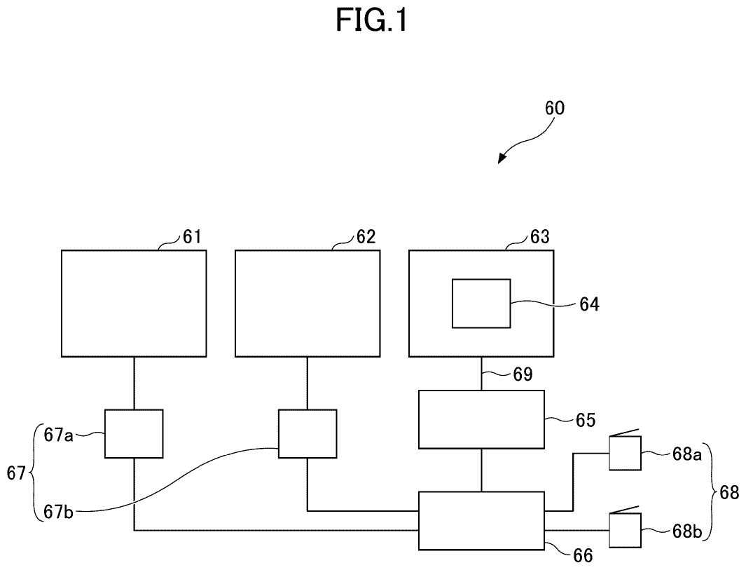

FIG. 1 is a diagram illustrating the configuration of a magnetic recording medium production apparatus according to one embodiment. The magnetic recording medium production apparatus according to the present embodiment will be described with reference to FIG. 1. The magnetic recording medium production apparatus 60 according to the present embodiment includes a film deposition device 61, a lubricant application device 62, and a varnishing device 63.

The magnetic recording medium production apparatus 60 has a collection unit 64 for collecting data on the load amount at the time of varnish processing, a storage unit 65 for storing the collected data on the load amount, an operation unit 66 for performing an operation by using the stored data on the load amount, and a setting unit 67 for setting the manufacturing conditions of the film deposition device 61 or the lubricant application device 62 based on the operation result obtained by the operation unit 66. In the example illustrated in FIG. 1, the magnetic recording medium production apparatus 60 further includes an alarm unit 68 for issuing an alarm of the abnormality of the film deposition device 61 or the lubricant application device 62 based on the operation result obtained by the operation unit 66.

The magnetic recording medium production apparatus 60 may not include the setting unit 67, and may include the film deposition device 61, the lubricant application device 62, the varnishing device 63, the collection unit 64, the storage unit 65, the operation unit 66, and the alarm unit 68.

The setting unit 67 may include a setting unit 67a for setting the manufacturing conditions of the film deposition device 61 and a setting unit 67b for setting the manufacturing conditions of the lubricant application device 62, and the single setting unit 67 may set the manufacturing conditions of the film deposition device 61 or the lubricant application device 62.

The alarm unit 68 may generate a sound and may light or flash a lamp. The alarm unit 68 may also send an e-mail to a person in charge. The alarm unit 68 may include an alarm unit 68a for issuing an alarm of the abnormality of the film deposition device 61 and an alarm unit 68b for issuing an alarm of the abnormality of the lubricant application device 62, and the single alarm unit 68 may issue an alarm of the abnormality of the film deposition device 61 or the lubricant application device 62.

In FIG. 1, the collection unit 64 is provided in the varnishing device 63. In this case, the varnishing device 63 has an output unit 69 for outputting data of the load amount at the time of varnish processing to the outside. The output unit 69 may output data of the load amount at the time of varnish processing to the storage unit 65.

As a different embodiment from FIG. 1, the collection unit 64 may be provided in another device outside the varnishing device 63. The storage unit 65 and the operation unit 66 may be provided in the varnishing device 63, the film deposition device 61, or the lubricant application device 62. The alarm unit 68a for issuing an alarm of the abnormality of the film deposition device 61 may be provided in the film deposition device 61, and the alarm unit 68b for issuing an alarm of the abnormality of the lubricant application device 62 may be provided in the lubricant application device 62.

In FIG. 1, the setting unit 67a for setting the manufacturing conditions of the film deposition device 61 preferably performs the setting automatically based on the operation result obtained by the operation unit 66, but the manufacturing conditions of the film deposition device 61 may be set manually.

In FIG. 1, the setting unit 67b for setting the manufacturing conditions of the lubricant application device 62 preferably performs the setting automatically based on the operation result obtained by the operation unit 66, but the manufacturing conditions of the lubricant application device 62 may be set manually.

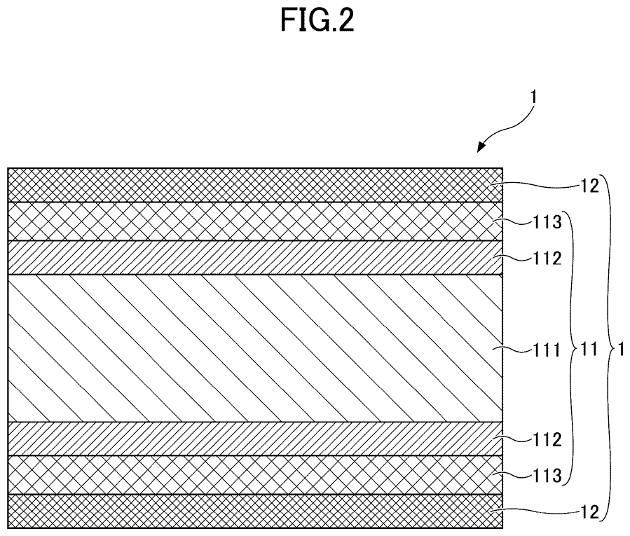

FIG. 2 is a cross-sectional view illustrating an example of a magnetic recording medium manufactured by the magnetic recording medium production apparatus according to one embodiment. As illustrated in FIG. 2, a magnetic recording medium 1 manufactured by the magnetic recording medium production apparatus 60 has lubrication layers 12 on both surfaces of a laminate 11 (also referred to as a laminated body).

The laminate 11 is provided with a magnetic recording layer 112 and a protective layer 113 laminated in this order from the substrate 111 side, on both surfaces of the substrate 111.

The substrate 111 is formed of a nonmagnetic material. For the substrate 111, a metal substrate made of a metal material such as an aluminum alloy may be used, or a non-metal substrate made of a non-metal material such as glass may be used. A NiP alloy layer may be formed on the surface of the metal substrate or the non-metal substrate by, for example, plating or sputtering.

The magnetic recording layer 112 is provided for recording and reproducing information, for example, to store data by reversing the direction of magnetization by magnetic energy supplied from the magnetic head of a HDD and maintaining the state of magnetization.

For the magnetic recording layer 112, FePt alloy having an L1₀ structure, CoPt alloy having an HCP (hexagonal close-packed) structure, CoCrPt alloy having an HCP structure and the like are used.

For the film deposition of the magnetic recording layer 112, known methods such as a sputtering method and an ion beam film deposition method can be used.

The protective layer 113 is provided to prevent corrosion of the magnetic recording layer 112, to prevent damage to the surface of the magnetic recording medium 1 when the magnetic head contacts the magnetic recording medium 1, and to enhance the corrosion resistance of the magnetic recording medium 1.

The protective layer 113 can be formed of known materials, such as a hard carbon film or diamond like carbon (DLC).

The protective layer 113 can be formed by a known method such as a sputtering method or an ion beam deposition method.

The surface of the protective layer 113 may be hydrogenated or nitrogenated. By hydrogenating or nitrogenating the surface of the protective layer 113, the bonding force with the lubrication layer 12 formed thereon can be enhanced. That is, because the first lubricant applied on the protective layer 113 has polarity, it forms a strong bond with hydrogen atoms and nitrogen atoms on the surface of the protective layer 113. The surface of the protective layer 113 is preferably nitrogenated.

The lubrication layer 12 is provided to reduce wear of the surfaces of the magnetic head and the magnetic recording medium 1 when the magnetic head contacts the magnetic recording medium 1, and to enhance the corrosion resistance of the magnetic recording medium 1.

The thickness of the lubrication layer 12 is preferably 5 Å to 10 Å. By making the thickness of the lubrication layer 12 5 Å to 10 Å, abrasion of the surface of the magnetic recording medium 1 can be reduced, corrosion resistance of the magnetic recording medium 1 can be enhanced, and high recording density can be implemented by shortening the distance between the magnetic head and the magnetic recording medium 1 in the HDD.

The inventors of the present invention analyzed the load amount at the time of varnishing in detail, and found that there is a correlation between the load amount at the time of varnishing, the surface roughness of the processing target, and the film thickness of the lubrication layer 12. If the magnetic recording medium production apparatus 60 resets the manufacturing conditions of the film deposition device 61 or the lubricant application device 62 by using this result, the generation of defective products in the corresponding device can be prevented. In the present specification, the surface roughness means the arithmetic average roughness (Ra), and can be measured in an area of a 10 μm or 1 μm-per side square by using, for example, an AFM (atomic force microscope).

If the magnetic recording medium production apparatus 60 cannot address a problem by resetting manufacturing conditions or does not reset the manufacturing conditions, an alarm can be issued to stop the film deposition device 61 or the lubricant application device 62, thereby preventing the generation of defective products in the corresponding device.

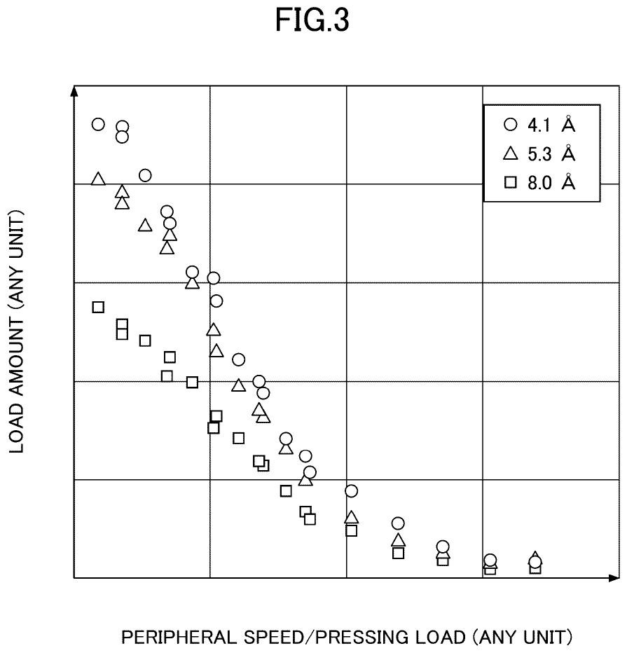

FIG. 3 is a diagram illustrating the relationship between the load amount and the film thickness of the lubrication layer at the time of varnishing. In FIG. 3, the horizontal axis represents the value obtained by dividing the peripheral speed (cm/sec) of the processing target surface (the surface of the lubrication layer 12) with respect to the polishing tape (tape containing an abrasive) 40 described later, by the pressing load (gf/cm²) of the polishing tape 40 on the processing target surface. The vertical axis represents the tension (gf) applied to the polishing tape 40 during varnish processing. The relationship between the value of the horizontal axis and the value of the vertical axis was examined by varying the film thickness of the lubrication layer 12 on the processing target surface with a film thickness of 4.1 Å, 5.3 Å, and 8.0 Å.

As illustrated in FIG. 3, when the film thickness of the lubrication layer 12 is changed, the tension (gf) applied to the polishing tape 40, that is, the load amount during varnish processing also changes, and it can be seen that this amount of change becomes more pronounced as the peripheral speed of the polishing tape 40 is decreased or the pressing load is increased.

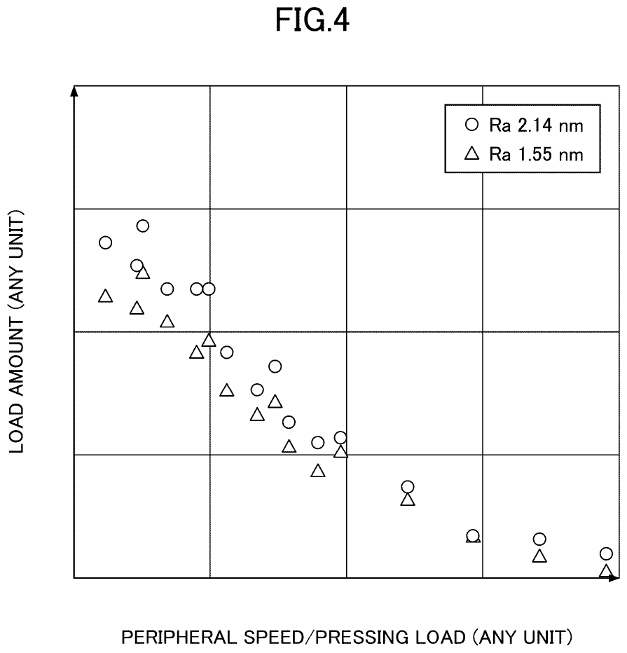

FIG. 4 is a diagram illustrating the relationship between the load amount during varnish processing and the surface roughness of the processing target. Here, the processing target is the laminate 11 on which lubrication layers 12 are formed on both sides. In FIG. 4, the horizontal axis represents the value obtained by dividing the peripheral speed (cm/sec) of the processing target surface relative to the polishing tape 40 by the pressing load (gf/cm²) of the polishing tape 40 on the processing target surface. The vertical axis represents the tension (gf) applied to the polishing tape 40 during processing. The relationship between the value of the horizontal axis and the value of the vertical axis was examined by varying the surface roughness of the processing target with surface roughnesses of 2.14 nm and 1.55 nm.

As illustrated in FIG. 4, when the surface roughness of the processing target is changed, the tension applied to the polishing tape 40, that is, the load amount during varnish processing also changes, and this change amount becomes more pronounced as the peripheral speed of the polishing tape 40 is decreased or the pressing load is increased.

From the above results, it can be understood that variations in the film thickness of the lubrication layer 12 on the processing target surface and variations in the surface roughness of the processing target can be detected by collecting and storing the load amount during varnish processing, and performing an operation by using the plurality of pieces of information stored (the load amount at the time of varnish processing, the peripheral speed of the processing target surface with respect to the polishing tape 40, the pressing load of the polishing tape to the processing target surface, the tension applied to the polishing tape 40 at the time of varnish processing, etc.). Therefore, by detecting variations in the film thickness of the lubrication layer 12 on the processing target surface or variations in the surface roughness of the processing target, the generation of defective products can be detected at an early stage and the generation of defective products can be predicted. Further, according to variations in the film thickness of the lubrication layer 12 on the processing target surface or variations in the surface roughness of the processing target, the manufacturing conditions of the film deposition device 61 and the lubricant application device 62 can be reset (changed), and it is also possible to detect abnormalities in the film deposition device 61 and the lubricant application device 62 and issue an alarm.

That is, by using the magnetic recording medium production apparatus 60, the generation of defective products during the production of the magnetic recording medium can be detected at an early stage or the generation of defective products can be predicted to increase the productivity of the magnetic recording medium.

Specifically, the operation unit 66 can calculate the amount of change in the film thickness of the lubrication layer 12 or the amount of change in the surface roughness of the processing target during varnish processing in the varnishing device 63 based on the correlation illustrated in FIG. 3 or FIG. 4, for example, using the data of the load amount stored in the storage unit. In this case, the operation result obtained by the operation unit 66 means the amount of change in the film thickness of the lubrication layer 12 or the amount of change in the surface roughness of the processing target.

### [Film Deposition Device]

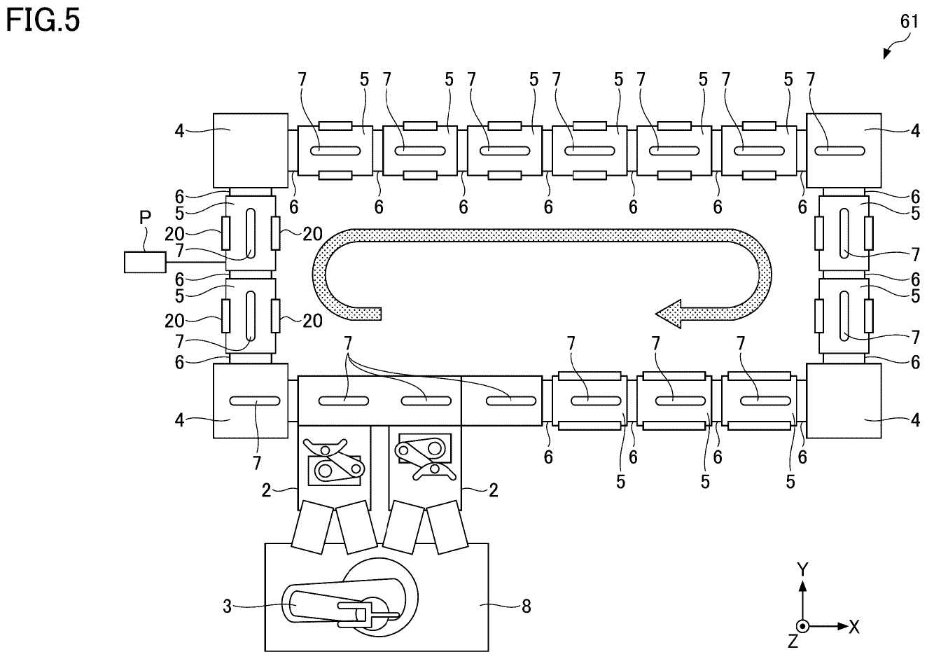

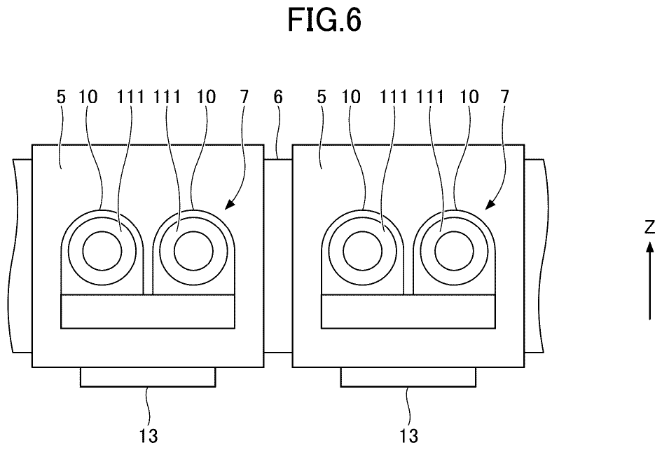

FIG. 5 is a plan view of a film deposition device according to one embodiment, and FIG. 6 is a side view of a chamber of the film deposition device according to one embodiment. In the present embodiment, an example of an in-line film deposition device 61 will be described. In the film deposition device 61, at least a magnetic recording layer 112 and a protective layer 113 are deposited on a substrate 111 in this order.

Generally, a sputtering method, a CVD method, a PVD method, or the like is used for the deposition of each layer of a magnetic recording medium, and in many cases, the deposition is carried out by each method by causing the inside of the film deposition device to become a vacuum state and introducing a processing gas into the film deposition device. In such a production method, it is preferable to perform the deposition continuously by using one film deposition device.

In the in-line type film deposition device, by performing the film deposition continuously, it is possible to reduce the contamination of the substrate at the time of handling, or to improve the efficiency of the manufacturing process and the yield of the product by reducing the number of handling steps, and to increase the productivity of the magnetic recording medium.

As illustrated in FIG. 5, the film deposition device 61 includes a robot stand 8, a substrate transfer robot 3 placed on the robot stand 8, a substrate attaching/detaching robot 2 adjacent to the robot stand 8, and a plurality of corner chambers 4 for rotating a carrier 7. Further, as illustrated in FIGS. 5 and 6, the film deposition device 61 is provided with a plurality of chambers 5 arranged between the corner chambers 4 for performing film deposition processing on a substrate 111, a plurality of carriers 7 holding the substrate 111 and successively conveyed in the plurality of corner chambers 4 and the plurality of chambers 5, and a processing mechanism 20 for processing both surfaces of the substrate 111. Although the processing mechanism 20 is provided in all of the chambers 5 in FIG. 5, the reference numeral “20” is partially omitted.

The film deposition device 61 further includes a vacuum pump P for decompressing the inside of the plurality of chambers 5, and a gate valve 6 for making the inside of the chambers 5 a sealed space. Although the vacuum pump P is provided in all of the chambers 5 in FIG. 5, the reference numeral P is partially omitted. In the example illustrated in FIG. 5, a gate valve 6 is provided at the connection portion of each chamber 5, and when each gate valve 6 is closed, the inside of each chamber 5 becomes an independent sealed space. A vacuum pump P may be connected to each chamber 5, and the inside of each chamber 5 is decompressed by the operation of the vacuum pump P. At least one of the plurality of chambers 5 has a heating mechanism for the substrate 111 as a processing mechanism 20.

The film deposition device 61 sequentially transports the carrier 7 into each chamber 5 by means of a transport mechanism 13 described later, and sequentially forms, for example, a soft magnetic layer, an intermediate layer, a magnetic recording layer 112, and a protective layer 113 on both surfaces of the substrate 111 held by the carrier 7 in each chamber 5 by means of a processing mechanism 20. After the protective layer 113 is formed over the substrate 111, the substrate 111 is taken out from the film deposition device 61, and lubrication layers 12 are formed over both surfaces of the substrate 111, thereby finally obtaining the magnetic recording medium 1 illustrated in FIG. 2.

Each corner chamber 4 is a chamber for changing the moving direction of the carrier 7, and a mechanism for rotating the carrier 7 and moving it to the next chamber 5 is provided in each corner chamber 4.

As illustrated in FIG. 6, the film deposition device 61 includes a transport mechanism 13 for transporting the carrier 7 into the gate valve 6 and the chamber 5. The transport mechanism 13 includes, for example, a linear motor drive mechanism for driving objects in a non-contact state. The carrier 7 is provided with a substrate holder 10 for holding the substrate 111 in a vertical position. The vertical position means a state in which the primary surface (front or back surface) of the substrate 111 is parallel to the vertical direction Z. In the present embodiment, 2 substrate holders 10 are arranged in the carrier 7, but the number of substrate holders 10 provided in the carrier 7 is not limited.

In the linear motor drive mechanism, a plurality of magnets are arranged in the lower part of the carrier 7 such that N poles and S poles are alternately arranged, and a rotating magnet in which N poles and S poles are alternately arranged in a spiral shape is arranged below the plurality of magnets by being separated by a partition, along the conveying path. The linear motor drive mechanism conveys the carrier 7 by rotating the rotating magnet around the axis while magnetically coupling the magnet on the carrier 7 side with the rotating magnet in a non-contact manner.

In the sputtering method, a target containing a material for forming the magnetic recording layer 112 can be used.

As the target containing a material for forming the magnetic recording layer 112, for example, an FePt alloy having an L1₀ structure, a CoPt alloy having an HCP structure, and a CoCrPt alloy having an HCP structure can be used.

As the sputtering method, a DC sputtering method, a DC magnetron sputtering method, and an RF sputtering method can be used.

When forming the magnetic recording layer 112, RF (Radio Frequency) bias, DC bias, pulsed DC, pulsed DC bias, or the like may be used as appropriate.

As the reactive gas, O₂ gas, H₂O gas, N₂ gas, or the like may be used.

The sputtering gas pressure is suitably adjusted to optimize the characteristics of each layer, but is usually within the range of, for example, 0.1 Pa to 30 Pa.

The formation method of the protective layer 113 is not particularly limited, but general film deposition methods such as, for example, the RF-CVD (Radio Frequency-Chemical Vapor Deposition) method, in which a film is formed by decomposing a source gas consisting of hydrocarbons with a high-frequency plasma, the IBD (Ion Beam Deposition) method, in which a film is formed by ionizing the source gas with electrons emitted from a filament, and the FCVA (Filtered Cathodic Vacuum Arc) method, in which a film is formed by using a solid carbon target without using a source gas, can be used.

The film deposition process of each layer of the magnetic recording medium, for example, the film deposition process of the protective layer 113, strongly affects the surface roughness of the magnetic recording medium. Therefore, if an abnormality is detected from the load amount during varnishing, the film deposition condition is reset, and if the problem cannot be addressed by the reset of the film deposition condition, the film deposition device is stopped by issuing an alarm, thereby preventing the generation of defective products.

Specifically, the setting unit 67 may set the film deposition condition of the film deposition device 61, such as the film deposition time and the film deposition speed, based on the operation result obtained by the operation unit 66. As a result, the setting unit 67 can reset the manufacturing condition of the film deposition device 61 to prevent the generation of defective products based on the operation result obtained by the operation unit 66. Therefore, the magnetic recording medium production apparatus 60 can reduce the generation of defective products at a stage prior to the varnishing process and increase the productivity of the magnetic recording medium.

The setting unit 67 may set the film deposition condition of the film deposition device 61, such as the film deposition time and the film deposition speed, when it determines that the amount of change in the surface roughness of the processing target, which is the operation result obtained by the operation unit 66, is greater than or equal to a threshold determined in advance.

The alarm unit 68 may issue an alarm of the abnormality of the film deposition device 61 when it determines that the amount of change in the surface roughness of the processing target is greater than or equal to a threshold determined in advance based on the operation result obtained by the operation unit 66. As a result, the user can recognize the abnormality of the film deposition device 61. Therefore, the magnetic recording medium production apparatus 60 can reduce the generation of defective products at a stage prior to the varnishing process and increase the productivity of the magnetic recording medium. The alarm unit 68 may issue an alarm of the abnormality of the film deposition device 61 and stop the film deposition device 61 when it determines that the amount of change in the surface roughness of the processing target is greater than or equal to a threshold determined in advance based on the operation result obtained by the operation unit 66.

### [Lubricant Application Device]

The lubricant application device 62 applies lubricant onto the protective layer 113 formed by the film deposition device 61 to form a lubrication layer 12. Examples of the lubricant application device 62 include lubricant application devices that perform a dip method, a spin coat method, a vapor method, and the like.

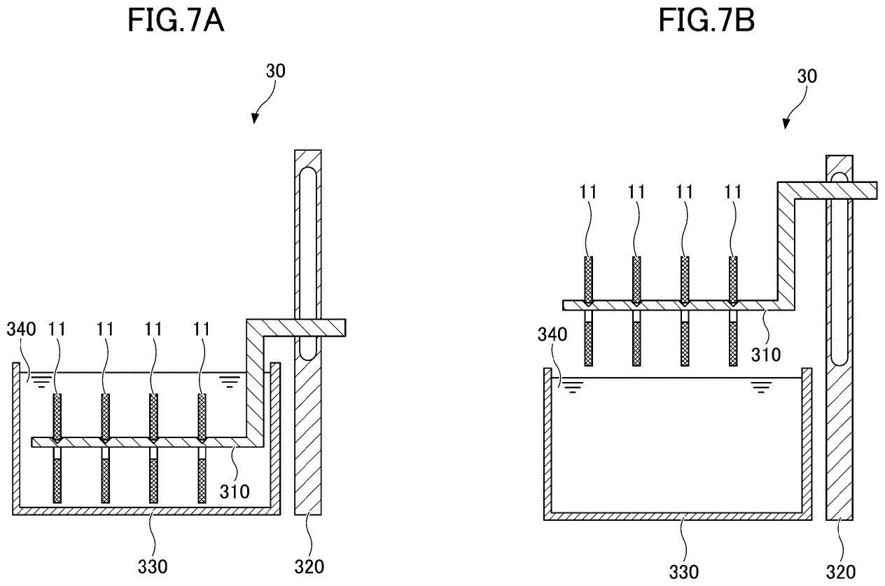

FIGS. 7A and 7B are diagrams for explaining the operation of the lubricant application device that performs a dip method. In FIGS. 7A and 7B, the order of operation is illustrated in the order of FIG. 7A and FIG. 7B. In the example illustrated in FIGS. 7A and 7B, the lubricant application device 30 includes a solution tank 330 containing a liquid 340 containing a lubricant, an arm 310 for holding the substrate 111 (the laminate 11) formed by the film deposition device 61, and a support 320 for supporting the arm 310 so as to be movable in the vertical direction. That is, the arm 310 is attached to the support 320 so as to be movable in the vertical direction.

As illustrated in FIG. 7A, a liquid 340 containing a lubricant is put into the solution tank 330, and the arm 310 to which the laminate 11 is fixed is lowered vertically at a constant speed into the liquid 340, to immerse the laminate 11 in the liquid 340. Then, the arm 310 is pulled up vertically at a constant speed to obtain the state illustrated in FIG. 7B, whereby the lubrication layer 12 can be formed on the surface of the laminate 11. Here, the laminate 11 is held by the arm 310 so that its inner circumference is caught by a V-shaped groove provided in the arm 310. The arm 310 is attached such that it can move vertically with respect to the support 320.

The film thickness of the lubrication layer 12 can be controlled by the pulling speed of the arm 310 or the lubricant concentration in the liquid 340. Therefore, when an abnormality in the film thickness of the lubrication layer 12 is detected from the load amount at the time of varnishing, the pulling speed of the arm 310 or the lubricant concentration in the liquid 340 can be reset, and when the abnormality cannot be addressed by resetting the pulling speed of the arm 310 or the lubricant concentration in the liquid 340, the lubricant application device can be stopped by issuing an alarm to prevent the generation of defective products.

Specifically, the setting unit 67 may set the pulling speed of the arm 310 of the lubricant application device 30 or the lubricant concentration in the liquid 340 based on the operation result obtained by the operation unit 66. Thus, the setting unit 67 can reset the manufacturing conditions of the lubricant application device 30 based on the operation result obtained by the operation unit 66 to prevent the generation of defective products. Therefore, the magnetic recording medium production apparatus 60 can reduce the generation of defective products at a stage prior to the varnishing process and improve the productivity of the magnetic recording medium.

The setting unit 67 may set one or more of the setting of the pulling speed of the arm 310 of the lubricant application device 30 and the setting of the concentration of the lubricant to the liquid 340 when it determines that the amount of change in the film thickness of the lubrication layer 12, which is the result of the operation by the operation unit 66, is greater than or equal to the threshold determined in advance.

The alarm unit 68 may issue an alarm of the abnormality of the lubricant application device 62 when it determines that the amount of change in the film thickness of the lubrication layer 12 is greater than or equal to the threshold determined in advance based on the result of the operation by the operation unit 66. Thus, because the user can recognize the abnormality of the lubricant application device 62, the magnetic recording medium production apparatus 60 can reduce the generation of defective products at a stage prior to the varnishing process and improve the productivity of the magnetic recording medium. The alarm unit 68 may issue an alarm of the abnormality of the lubricant application device 62 and stop the lubricant application device 62 when it determines that the amount of change in the film thickness of the lubrication layer 12 is greater than or equal to the threshold determined in advance based on the result of the operation by the operation unit 66.

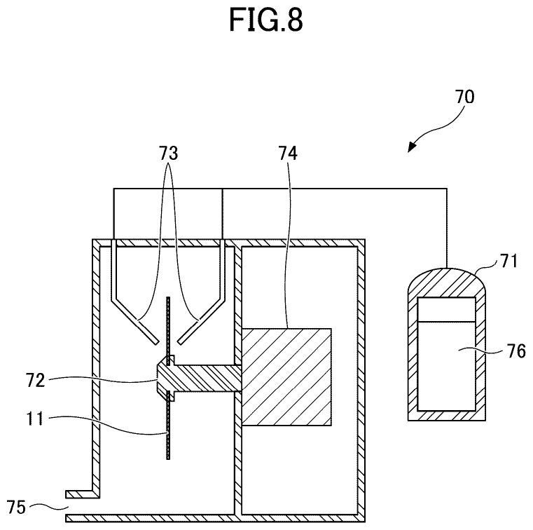

FIG. 8 is a schematic configuration diagram of the lubricant application device that performs the spin coating method. As illustrated in FIG. 8, the lubricant application device 70 that performs the spin coating method prepares the liquid 76 containing the lubricant in the tank 71. The liquid 76 is sprayed from the nozzle 73 onto both surfaces of the laminate 11 chucked in the spindle 72, and then the laminate 11 is rotated at high speed by the motor 74 for a fixed time to form a lubrication layer 12 on the laminate 11 by centrifugal force. The excess liquid 76 is discharged from the drain port 75 to the outside of the device. The film thickness of the lubrication layer 12 can be controlled by the rotation speed of the spindle 72 and the lubricant concentration in the liquid 76. Therefore, when abnormality in the film thickness of the lubrication layer 12 is detected from the load amount at the time of varnishing, the rotation speed of the spindle 72 and the lubricant concentration in the liquid 76 are reset, and when the abnormality cannot be addressed by resetting the rotation speed of the spindle 72 and the lubricant concentration in the liquid 76, the lubricant application device 70 is stopped by issuing an alarm, thereby preventing the generation of defective products.

Specifically, the setting unit 67 may set the rotation speed of the spindle 72 of the lubricant application device 70 or the concentration of the lubricant to the liquid 76 based on the operation result obtained by the operation unit 66. Thus, the setting unit 67 can reset the manufacturing conditions of the lubricant application device 70 based on the operation result obtained by the operation unit 66 to prevent the generation of defective products. Therefore, the magnetic recording medium production apparatus 60 can reduce the generation of defective products at a stage prior to the varnishing process and improve the productivity of the magnetic recording medium.

The setting unit 67 may set one or more of the setting of the rotation speed of the spindle 72 of the lubricant application device 70 and the setting of the concentration of the lubricant to the liquid 76 when it determines that the amount of change in the film thickness of the lubrication layer 12, which is the operation result obtained by the operation unit 66, is greater than or equal to a threshold determined in advance.

Based on the operation result obtained by the operation unit 66, the alarm unit 68 may issue an alarm of the abnormality of the lubricant application device 70 when it determines that the amount of change in the film thickness of the lubrication layer 12 is greater than or equal to a threshold determined in advance. Thus, because the user can recognize the abnormality of the lubricant application device 70, the magnetic recording medium production apparatus 60 can reduce the generation of defective products at a stage prior to the varnishing process and improve the productivity of the magnetic recording medium. Based on the operation result obtained by the operation unit 66, the alarm unit 68 may issue an alarm of the abnormality of the lubricant application device 70 and stop the lubricant application device 70 when it determines that the amount of change in the film thickness of the lubrication layer 12 is greater than or equal to a threshold determined in advance.

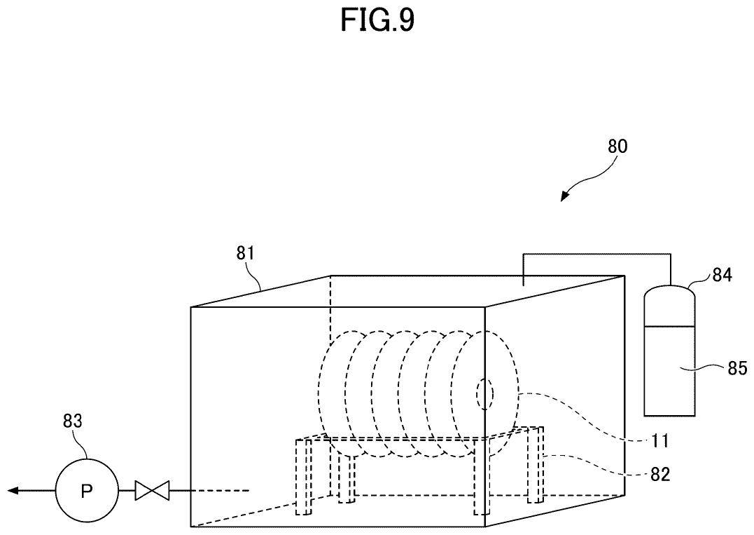

FIG. 9 is a schematic configuration diagram of the lubricant application device that performs the vapor method. In the lubricant application device 80 that performs the vapor method, as illustrated in FIG. 9, after the laminate 11 is placed on the installation table 82 in the processing chamber 81, the inside of the processing chamber 81 is exhausted by a vacuum pump 83. Thereafter, the lubricant 84 gasified by heating is introduced into the processing chamber 81 to form the lubrication layer 12 on the laminate 11. After that, the inside of the processing chamber 81 is vacuum-exhausted, the inside of the processing chamber 81 is brought to atmospheric pressure, and the processed substrate is taken out from the inside of the processing chamber 81. The film thickness of the lubrication layer 12 can be controlled by the introduction amount of the gasified lubricant. Therefore, when abnormality in the film thickness of the lubrication layer 12 is detected from the load amount at the time of varnishing, the lubricant introduction amount is reset, and when the abnormality cannot be addressed by the reset of the lubricant introduction amount, the lubricant application device 80 is stopped by issuing an alarm to prevent the generation of defective products.

Specifically, the setting unit 67 may set the lubricant introduction amount of the lubricant application device 80 based on the operation result obtained by the operation unit 66. Thus, the setting unit 67 can reset the manufacturing conditions of the lubricant application device 80 based on the operation result obtained by the operation unit 66 to prevent the generation of defective products. Therefore, the magnetic recording medium production apparatus 60 can reduce the generation of defective products at a stage prior to the varnishing process and improve the productivity of the magnetic recording medium.

The setting unit 67 may make a setting to raise or lower the lubricant introduction amount of the lubricant application device 80 when it is determined that the amount of change in the film thickness of the lubrication layer 12, which is the operation result obtained by the operation unit 66, is greater than or equal to a threshold determined in advance.

The alarm unit 68 may issue an alarm of the abnormality of the lubricant application device 80 when it is determined that the amount of change in the film thickness of the lubrication layer 12 is greater than or equal to a threshold determined in advance based on the operation result obtained by the operation unit 66. Thus, because the user can recognize the abnormality of the lubricant application device 80, the magnetic recording medium production apparatus 60 can reduce the generation of defective products at a stage prior to the varnishing process and improve the productivity of the magnetic recording medium. When the alarm unit 68 determines, based on the operation result obtained by the operation unit 66, that the amount of change in the film thickness of the lubrication layer 12 is greater than or equal to a threshold determined in advance, it may issue an alarm of the abnormality of the lubricant application device 80 and stop the lubricant application device 80.

The organic compound used as the lubricant preferably contains a hydroxyl group, an amino group, an amide group, a carbonyl group, a carboxyl group, a cyano group, a phenyl group, a methyl group, and the like as a functional group, and among these, a hydroxyl group, an amino group, an amide group, a carbonyl group, a carboxyl group, and a cyano group are particularly preferably contained as a functional group having polarity (polar group).

The weight average molecular weight (Mw) of the compound constituting the lubricant is preferably 900 to 3000, and the structural formula of the lubricant preferably contains the aforementioned polar groups in the range of 4 to 8 groups. In the present specification, the weight average molecular weight refers to a value measured by gel permeation chromatography (GPC).

### [Varnishing Device]

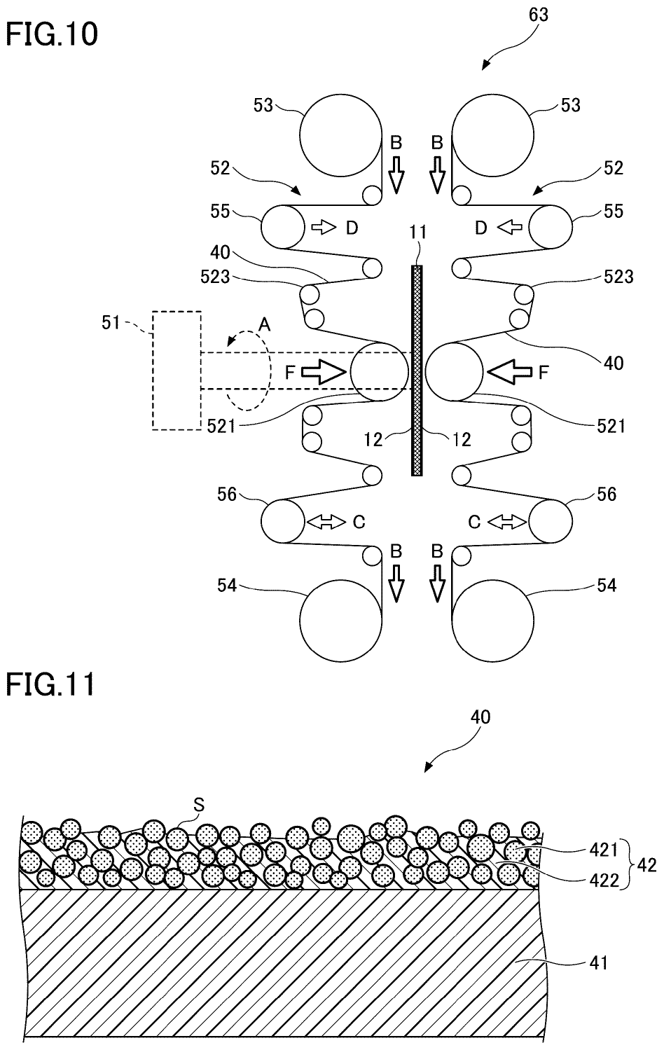

FIG. 10 is a diagram illustrating an example of a varnishing device according to the present embodiment. In the varnishing device 63, the surface of the lubrication layer 12 applied by the lubricant application device 30 is subjected to a varnishing process by using a polishing material. As illustrated in FIG. 10, the varnishing device 63 has a pair of polishing tapes 40, the polishing tapes 40 being arranged oppositely so as to sandwich the laminate 11 having the lubrication layers 12 formed on both sides thereof, a rotation supporting unit 51 (dashed line in the figure) for rotating the laminate 11 having the lubrication layers 12 formed on both sides thereof in the direction of an arrow A, and a tape moving unit 52 for moving the polishing tape 40 in the direction of an arrow B. The tape moving unit 52 includes a polishing tape supply reel 53, multiple guide rolls 523, and a polishing tape winding reel 54.

Each of the two of polishing tapes 40 is supplied from the polishing tape supply reel 53 in a state of being wound in a roll, moves in the direction of an arrow B while being guided by the multiple guide rolls 523, and is wound in a roll by the polishing tape winding reel 54 (in the figure, the reference numeral “523” of the guide roll is partially omitted).

In the varnishing device 63, the polishing tapes 40 are arranged oppositely so as to sandwich the laminate 11 having the lubrication layers 12 formed on both sides thereof, so that varnishing can be performed efficiently on both sides of the lubrication layer 12 at a similar time.

FIG. 11 is an enlarged cross-sectional view illustrating an example of the polishing tape 40 used for varnishing. As illustrated in FIG. 11, the polishing tape 40 polishes the lubrication layer 12 by sliding the polishing surface S against the surface of the lubrication layer 12.

The polishing tape 40 has a polishing material layer 42 on a support 41. The polishing material layer 42 has abrasive grains 421 and a binder 422 for bonding the abrasive grains 421 to each other, bonding the abrasive grains 421 to the support 41, and fixing the abrasive grains 421 to the polishing material layer 42.

The material constituting the support 41 is not particularly limited, and various resins such as polyethylene terephthalate are used.

Examples of the abrasive grains 421 include particles having chromium oxide, α-alumina, silicon carbide, nonmagnetic iron oxide, diamond, γ-alumina, α, γ-alumina, fused alumina, corundum, artificial diamond, and the like. The abrasive grains 421 may be a suitable combination of two or more of these types.

Examples of the binder 422 are not particularly limited, and thermosetting resin, thermoplastic resin, photosensitive resin, and the like can be used. One type of resin used as the binder 422 may be used alone, or two or more types may be used in combination.

Because the polishing tape 40 is long, it is supplied in a rolled state, and in this state, it is set on the polishing tape supply reel 53 of the varnishing device 63 for use.

The rotation supporting unit 51 rotates the laminate 11 having the lubrication layers 12 on both sides in a circumferential direction (direction of arrow A) while supporting the central opening of the laminate 11 having the lubrication layers 12 on both sides. The direction of arrow A may be an opposite direction.

The tape moving unit 52 presses the polishing tape 40 on both surfaces of the rotated laminate 11 having the lubrication layers 12 on both sides in the direction of arrow F, and moves the polishing tape 40 relatively in the radial direction of the laminate 11 having the lubrication layers 12 on both sides as appropriate. A polishing tape pressing unit 521 may be referred to as a contact roll.

In the varnishing device 63, a tape tension sensor 55 and a tape tension controller 56 are provided in the polishing tape running system. The tape tension sensor 55 detects the tensile force (tape tension) applied to the polishing tape and outputs the detected tensile force. The tape tension controller 56 eliminates the tensile force and bending applied to the polishing tape 40 when the polishing tape pressing unit 521 moves, and reduces the tensile force applied to the polishing tape 40 on the downstream side from the polishing tape pressing unit 521 within a predetermined range during varnishing. That is, when the polishing tape pressing unit 521 moves in the direction of the arrow F, the polishing tape 40 is pulled, and when it moves in the direction opposite to the arrow F, the polishing tape 40 is bent, but the tape tension controller 56 displaces in the direction of the arrow C to eliminate the bending. The tape tension controller 56 also applies a constant tension to the polishing tape 40 on the downstream side from the polishing tape pressing unit 521 during varnishing to prevent the polishing tape 40 from loosening.

In the varnishing device 63, the tensile force applied to the polishing tape 40 can be controlled by the rotational force of the polishing tape winding reel 54 and the polishing tape supply reel 53. That is, the tensile force applied to the polishing tape 40 can be set to a predetermined value by controlling the rotational force of the polishing tape winding reel 54 and the polishing tape supply reel 53 based on the tensile force of the polishing tape 40 detected by the tape tension sensor 55.

In the varnishing device 63, the tensile force applied to the polishing tape 40 can be detected as a pressing load in the direction of arrow D by using the tape tension sensor 55. This can be used as a load amount during varnishing. That is, the tensile force of the polishing tape 40 before the varnishing process is performed by pressing the polishing tape 40 against the lubrication layer 12 by the polishing tape pressing unit 521 is measured, and the tensile force of the polishing tape 40 during the varnishing process is measured, and the load amount in the varnishing process can be calculated from the difference between the two measured tensile forces.

The load amount in the varnishing process can also be calculated from the amount of change of the pressing load in the direction of arrow F of the polishing tape pressing unit 521, the amount of change of the rotational force of the polishing tape winding reel 54, and the amount of change of the rotational force of the polishing tape supply reel 53, immediately before the varnishing process and during the varnishing process.

Specifically, the collection unit 64 may collect data on the tensile force of the polishing tape 40 before the varnishing process is performed by pressing the polishing tape 40 against the lubrication layer 12, and the tensile force of the polishing tape 40 during the varnishing process, as data on the load amount, the output unit 69 may output these pieces of data to the storage unit 65, and the storage unit 65 may store these pieces of data. Then, the operation unit 66 may calculate the difference between the tensile force of the polishing tape 40 before the varnishing process is performed by pressing the polishing tape 40 against the lubrication layer 12, and the tensile force of the polishing tape 40 during the varnishing process. The operation unit 66 may further calculate the amount of change of the film thickness of the lubrication layer 12 or the amount of change of the surface roughness of the processing target during the varnishing process in the varnishing device 63 using the operation result of calculating the difference.

The collection unit 64 may collect data on the amount of change of the pressing load in the direction of arrow F of the polishing tape pressing unit 521, the amount of change of the rotational force of the polishing tape winding reel 54, or the amount of change of the rotational force of the polishing tape supply reel 53, immediately before the varnishing process and during the varnishing process, as data on the load amount. The output unit 69 may output these pieces of data to the storage unit 65, and the storage unit 65 may store these pieces of data. The operation unit 66 may use these pieces of data to calculate the amount of change in the film thickness of the lubrication layer 12 or the amount of change in the surface roughness of the processing target at the time of varnishing in the varnishing device 63.

When the varnishing device 63 has an output unit 69 for outputting the data of the load amount at the time of varnishing the surface to be polished with the polishing material, it is possible to detect the generation of defective products at an early stage during the production of the magnetic recording medium and to predict the generation of defective products.

### <Magnetic Recording Medium Production Method>

An example of the magnetic recording medium production method of the present embodiment will be described below. Because the members used in each step are similar to those in the above-described magnetic recording medium production apparatus 60, their description will be omitted here. The magnetic recording medium 1 produced by the magnetic recording medium production method of the present embodiment is similar to the magnetic recording medium 1 produced by the above-described magnetic recording medium production apparatus 60, and, therefore, the description thereof will be omitted here. The magnetic recording medium production method of the present embodiment includes a film deposition step, a lubricant application step, and a varnishing step.

### [Film Deposition Step]

The magnetic recording medium production method includes a film deposition step in which at least a magnetic recording layer 112 and a protective layer 113 are formed on a substrate 111 in this order. The film deposition step may be performed by using the film deposition device 61.

### [Lubricant Application Step]

The magnetic recording medium production method includes a lubricant application step in which a lubricant is applied on the protective layer 113 formed by the film deposition step to form the lubrication layer 12.

For the formation of the lubrication layer 12, known methods such as a dip method, a spin coat method, and a vapor method may be used. In the dip method, the lubrication layer 12 is formed on the surface of the laminate 11 by immersing the laminate 11 in a liquid in which a lubricant is dissolved, and then pulling up the laminate 11 at a constant speed. In the spin coat method, the lubrication layer 12 is formed on the surface of the laminate 11 by applying a liquid in which a lubricant is dissolved to the surface of the laminate 11, and then rotating the laminate 11 at a high speed for a fixed time. The vapor method is a method for forming the lubrication layer 12 on the laminate 11 by placing the laminate 11 in a vacuum container and introducing a gasified lubricant by heating into the vacuum container. The lubricant application step may be carried out using the lubricant application device 30, the lubricant application device 70, or the lubricant application device 80.

### [Varnishing Process]

The magnetic recording medium production method includes a varnishing process in which the surface of the lubrication layer applied by the lubricant application step is varnished with a polishing material.

In the varnishing process, a method in which the polishing tape 40 is pressed and rubbed against the surface of the laminate 11 having the lubrication layer 12 formed on both sides, can be used. The varnishing method and the varnishing device will be described in detail with reference to figures.

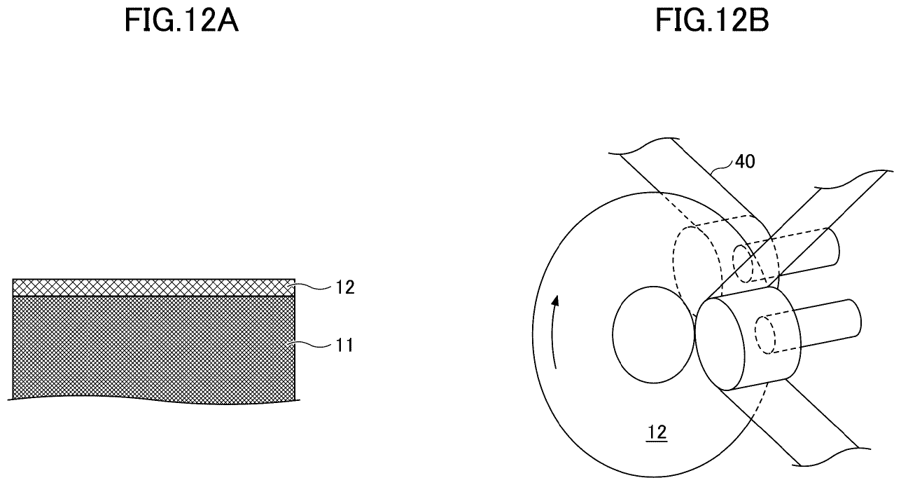

FIGS. 12A and 12B are diagrams for explaining the varnishing process, wherein FIG. 12A is a partial cross-sectional view of the laminate 11 on which the lubrication layer 12 is formed before the varnishing process, and FIG. 12B is a diagram illustrating a state during the varnishing process. As illustrated in FIG. 12A, a lubricant is applied on the laminate 11, and then, as illustrated in FIG. 12 (b), a varnishing process is performed to varnish the surface of the laminate 11 having the lubrication layers 12 formed on both sides, with a polishing tape 40.

In the varnishing process, the laminate 11 having the lubrication layers 12 formed on both sides is rotated, and the tape containing a polishing material is pressed and rubbed against the surface of the lubrication layer 12. The rotation speed of the substrate in the varnishing process is, for example, within a range of 500 rpm to 3000 rpm. Although the substrate is rotated clockwise in FIG. 12B, it may be rotated in the opposite direction. The varnishing process may be performed using the varnishing device 63.

The magnetic recording medium production method includes setting the manufacturing conditions of the film deposition process or the lubricant application process based on the load amount at the time of varnishing. The load amount at the time of varnishing may be similar to that in the above-mentioned magnetic recording medium production apparatus 60. Thus, according to the magnetic recording medium production method, the generation of defective products during the production of the magnetic recording medium can be detected at an early stage and the generation of defective products can be predicted.

The magnetic recording medium production method includes detecting an abnormality in the film deposition process or the lubricant application process based on the load amount during the varnish processing. The load amount during the varnish processing can be similar to that in the above-described magnetic recording medium production apparatus 60. Thus, according to the magnetic recording medium production method, the generation of defective products during the production of the magnetic recording medium can be detected at an early stage and the generation of defective products can be predicted.

Although the above-described embodiments have been described, the above-described embodiments are presented as examples, and the present invention is not limited by the above-described embodiments. The above-described embodiments can be implemented in various other forms, and various combinations, omissions, substitutions, and changes can be made without departing from the gist of the invention. These embodiments and variations thereof are included in the scope and gist of the invention, as well as in the corresponding scope of the invention and the claims.

According to one embodiment of the present disclosure, it is possible to provide a magnetic recording medium production apparatus, a magnetic recording medium production method, and a varnishing device which can enhance the productivity of the magnetic recording medium by early detection or prediction of the generation of defective products at the time of the production of the magnetic recording medium.

What is claimed is:

1. A magnetic recording medium production apparatus comprising:
a film deposition device configured to form at least a magnetic recording layer and a protective layer on a substrate, formed in an order of the magnetic recording layer followed by the protective layer;
a lubricant application device configured to form a lubrication layer by applying a lubricant on the protective layer formed by the film deposition device;
a varnishing device configured to perform a varnishing process, with a polishing material, on a surface of the lubrication layer applied by the lubricant application device;
a processor; and
a memory that includes instructions, which when executed, cause the processor to execute:
collecting data on a load amount during the varnishing process;
storing the collected data on the load amount;
performing an operation by using the stored data on the load amount; and
setting a manufacturing condition of the film deposition device or the lubricant application device based on an operation result obtained by performing the operation.

2. The magnetic recording medium production apparatus according to claim 1, wherein the performing of the operation includes obtaining an amount of change in a film thickness of the lubrication layer during the varnishing process or an amount of change in a surface roughness of a processing target during the varnishing process, by using the stored data on the load amount.

3. The magnetic recording medium production apparatus according to claim 1, wherein
the lubricant application device includes:
a solution tank configured to contain a liquid including the lubricant;
an arm configured to hold the substrate on which the magnetic recording layer and the protective layer are formed by the film deposition device; and
a support configured to support the arm so as to be movable in a vertical direction, and
the setting includes setting a pulling speed of the arm of the lubricant application device or a concentration of the lubricant with respect to the liquid, based on the operation result obtained by performing the operation.

4. A magnetic recording medium production apparatus comprising:
a film deposition device configured to form at least a magnetic recording layer and a protective layer on a substrate, formed in an order of the magnetic recording layer followed by the protective layer;
a lubricant application device configured to form a lubrication layer by applying a lubricant on the protective layer formed by the film deposition device;
a varnishing device configured to perform a varnishing process, with a polishing material, on a surface of the lubrication layer applied by the lubricant application device;
a processor; and
a memory that includes instructions, which when executed, cause the processor to execute:
collecting data on a load amount during the varnishing process;
storing the collected data on the load amount;
performing an operation by using the stored data on the load amount; and
issuing an alarm of an abnormality of the film deposition device or the lubricant application device based on an operation result obtained by performing the operation.

5. The magnetic recording medium production apparatus according to claim 4, wherein the performing of the operation includes obtaining an amount of change in a film thickness of the lubrication layer during the varnishing process or an amount of change in a surface roughness of a processing target during the varnishing process, by using the stored data on the load amount.

6. The magnetic recording medium production apparatus according to claim 5, wherein the issuing includes issuing the alarm of the abnormality of the lubricant application device, in response to determining that the amount of change in the film thickness of the lubrication layer is greater than or equal to a threshold determined in advance, based on the operation result obtained by performing the operation.

7. A magnetic recording medium production method comprising:
forming at least a magnetic recording layer and a protective layer on a substrate, formed in an order of the magnetic recording layer followed by the protective layer;
forming a lubrication layer by applying a lubricant on the formed protective layer;
performing a varnishing process, with a polishing material, on a surface of the applied lubrication layer; and
setting a manufacturing condition of forming at least the magnetic recording layer and the protective layer or the lubrication layer, based on a load amount during the varnishing process.

8. A magnetic recording medium production method comprising:
forming at least a magnetic recording layer and a protective layer on a substrate, formed in an order of the magnetic recording layer followed by the protective layer;
forming a lubrication layer by applying a lubricant on the formed protective layer;
performing a varnishing process, with a polishing material, on a surface of the applied lubrication layer; and
detecting an abnormality in forming at least the magnetic recording layer and the protective layer or the lubrication layer, based on a load amount during the varnishing process.

9. A varnishing device used for producing a magnetic recording medium, comprising:
a processor; and
a memory that includes instructions, which when executed, cause the processor to execute:
outputting data on a load amount during a varnishing process, performed with a polishing material, on a surface to be polished.
